(19) United States
(12) Patent Application Publication
(10) Pub. No.: US 2004/0212081 A1
(43) Pub. Date: Oct. 28, 2004

(54) Process for fabricating a power hybrid module

(76) Inventors: Patrick J. Carberry, Allentown, PA (US); Lawrence W. Golick, Allentown, PA (US); Juan A. Herbsommer, Berkeley Heights, NJ (US); Osvaldo Lopez, Lebenon, NJ (US); Michael Quinn, Allentown, PA (US); Hugo F. Safar, Berkeley Heights, NJ (US)

Correspondence Address: HARNESS, DICKEY & PIERCE, P.L.C., P.O. BOX 8910, Reston, VA, 20195, US

(21) Appl. No.: 10/408,448

(22) Filed: Apr. 8, 2003

(51) Int. Cl. H01L 23/34

(52) U.S. Cl. 257/717

(57) ABSTRACT

A process for fabricating a power hybrid module including placing at least one carrier assembly in at least one opening in at least one printed circuit board, mounting the at least one carrier assembly and the at least one printed circuit board on assembly tape, electrically connecting one of the at least one carrier assemblies and one of the at least one printed circuit boards, overmolding the at least one carrier assembly and the at least one printed circuit board and removing the assembly tape to produce a surface mount power hybrid module. A power hybrid module including at least one printed circuit board with at least one opening therein, at least one carrier assembly, positioned in the at least one opening such that said at least one carrier assembly may be surface mounted and electrically connected to the at least one printed circuit board, and an overmold over the at least one printed circuit board and the at least one carrier assembly.

### BACKGROUND OF THE INVENTION

1. Technical Field

This invention relates to the fabrication of power hybrid modules suitable for semiconductor devices.

2. Background Art

Power hybrid modules are utilized in high power semiconductor devices. An example of a conventional power hybrid module 10 in a ceramic package is illustrated in FIG. 1. The ceramic package 12 includes a ceramic ring 14 and a ceramic lid 16, sealed together with epoxy. The ceramic package 12 is secured to a base 18, such as a copper-tungsten (CuW) base. The ceramic package 12 defines an interior portion in which are placed a plurality of high power semiconductor chips 20, for example 1×5 mm LDMOS transistors formed from a wafer of Si and/or SiON gold (Au) metal capacitors. The high power semiconductor chips 20 are secured to the base 18 by a eutectic attachment, such as eutectic solder. The high power semiconductor chips 20 are connected to each other with wire 21, for example by 2 μm Au wire and also connected to leads 22 that extend from the sides of the ceramic package 12.

The conventional ceramic package illustrated in FIG. 1, is expensive and has several deficiencies. The conventional ceramic package of FIG. 1 is more than five times more expensive than the high power semiconductor chips 20, which is undesirable.

Further, conventional power hybrid modules, such as the conventional power hybrid module 10 of FIG. 1 are purchased and integrated into power amplifiers by power amplifier manufacturers. One feature of a power hybrid module is how closely the power hybrid module is impedance matched to 50Ω. High power transistors, such as the 1×5 mm) LDMOS transistor illustrated in FIG. 1, typically have an impedance less than 1Ω. The SiON Au capacitors are added to increase the impedance to 2-3Ω to better match the desired impedance of 50Ω. In short, the higher the impedance of a power hybrid module, the easier it is for a power amplifier manufacturer to integrate the power hybrid module into a power amplifier.

Another problem is the ceramic package 12 does not allow much room for the incorporation of additional circuitry, such as the SiON Au capacitors or other passive components that typically accompany power hybrid modules.

Additionally, power hybrid modules operate at high power, such as 50-150 Watts, which generates heat that must be dissipated. Because an LDMOS transistor is fairly small and the possibility of damage to the transistor due to heat is significant, some thermal management should be employed. As shown in FIG. 1, the CuW base 18 is a fairly thick metal plate, which is positioned between the power hybrid module 10 and a thermal heat sink on which the power hybrid module 10 is to be mounted. The thick CuW base 18 slows heat dissipation from the power hybrid module 10, which can adversely affect performance of the LDMOS transistor.

FIG. 2 illustrates a conventional plastic package 30, which affords some improvement. In particular, the conventional plastic package 30 as illustrated in FIG. 2 has an improved path for conducting heat from the chip 32 to a heat sink. The plastic package 30 illustrated in FIG. 2 is also a surface mount, in that the contacts 34 for input and output are at the bottom of the package, allowing the package itself to be surface mounted on a circuit board. However, plastic packages have a tendency to melt from the heat generated by the enclosed components.

An alternative plastic package 40 is illustrated in FIGS. 3-5. As illustrated in FIGS. 4 and 5, the plastic package 40 is not a surface mounted package, but rather a flange mount, as the leads 22 of FIGS. 4 and 5 extend from the side of the package 40. The plastic package 40 illustrated in FIGS. 3-5 is also deficient because the chips 44 are mounted on a first substrate 46, which are further mounted on a second substrate 42. In FIG. 5, the first substrate 46 is a carrier, which is surrounded by a PC board 48 and the second substrate 42 is a metal base. When the package 40 illustrated in FIGS. 3 and 4 is mounted on a heat sink, heat dissipation is difficult because the heat must conduct through several intervening layers (first substrate 46 and second substrate 42), before being dissipated by the heat sink. Also similar to the plastic package of FIG. 2, the plastic package of FIGS. 3-5 has a tendency to melt from the heat generated by the enclosed components.

### SUMMARY OF THE INVENTION

In one exemplary embodiment, the present invention is directed to a process for fabricating a power hybrid module, including placing at least one carrier assembly in at least one opening in at least one printed circuit board, mounting the at least one carrier assembly and the at least one printed circuit board on assembly tape, electrically connecting one of the at least one carrier assemblies and one of the at least one printed circuit boards, overmolding the at least one carrier assembly and the at least one printed circuit board, and removing the assembly tape to produce a surface mount power hybrid module.

In another exemplary embodiment, the present invention is directed to a process for fabricating a power hybrid module wherein several carrier assemblies are placed in several openings in several printed circuit boards and the several carrier assemblies are singulated.

In another exemplary embodiment, the present invention is directed to a process for fabricating a power hybrid module, including placing at least one die in at least one opening in at least one printed circuit board, mounting the at least one die and the at least one printed circuit board on assembly tape, electrically connecting one of the at least one dies and one of the at least one printed circuit boards, overmolding the at least one die and the at least one printed circuit board, and removing the assembly tape to produce a surface mount power hybrid module.

In another exemplary embodiment, the present invention is directed to a process for fabricating a power hybrid module wherein several dies are placed in several openings in several printed circuit boards and the several dies are singulated.

In another exemplary embodiment, the present invention includes impedance matching circuitry is mounted on the at least one printed circuit board.

In another exemplary embodiment, the present invention is directed to a process for fabricating a power hybrid module wherein the at least one carrier assembly includes at least one die or chip and at least one carrier.

In another exemplary embodiment, the present invention is directed to a process for fabricating a power hybrid module wherein the assembly tape is Kapton tape.

In another exemplary embodiment, the present invention is directed to a process for fabricating a power hybrid module wherein the overmolding is performed with plastic.

In another exemplary embodiment, the present invention is directed to a power hybrid module, including at least one printed circuit board with at least one opening therein, at least one carrier assembly, positioned in the at least one opening such that the at least one carrier assembly may be surface mounted and electrically connected to the at least one printed circuit board, and an overmold over the at least one printed circuit board and the at least one carrier assembly.

In another exemplary embodiment, the present invention is directed to a power hybrid module, including at least one printed circuit board with at least one opening therein, at least one die, positioned in the at least one opening such that the at least one die may be surface mounted and electrically connected to the at least one printed circuit board, and an overmold over the at least one printed circuit board and the at least one die.

In another exemplary embodiment, the present invention is directed to a power hybrid module, where the at least one carrier assembly includes at least one die or chip and at least one carrier.

In another exemplary embodiment, the present invention is directed to a power hybrid module, wherein the overmold is made of plastic.

In another exemplary embodiment, the present invention is directed to a power hybrid module which further includes impedance matching circuitry.

In another exemplary embodiment, the present invention is directed to a power hybrid module, where the at least one printed circuit board including at last one via.

### BRIEF DESCRIPTION OF THE DRAWINGS

FIG. 1 illustrates a conventional ceramic package.

FIGS. 2-5 illustrate conventional plastic packages.

FIGS. 6A-6E illustrate the process for fabricating a power hybrid module one exemplary embodiment of the present invention.

FIG. 7 illustrates a resulting power hybrid module, produced according to the exemplary method of FIGS. 6A-6E.

FIG. 8 is a photograph a power hybrid module in accordance with another exemplary embodiment of the present invention.

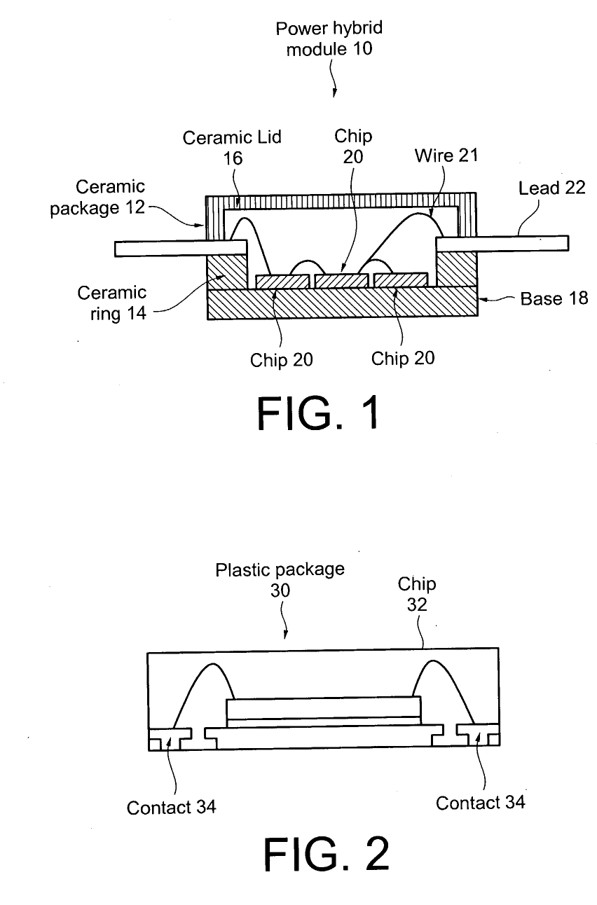

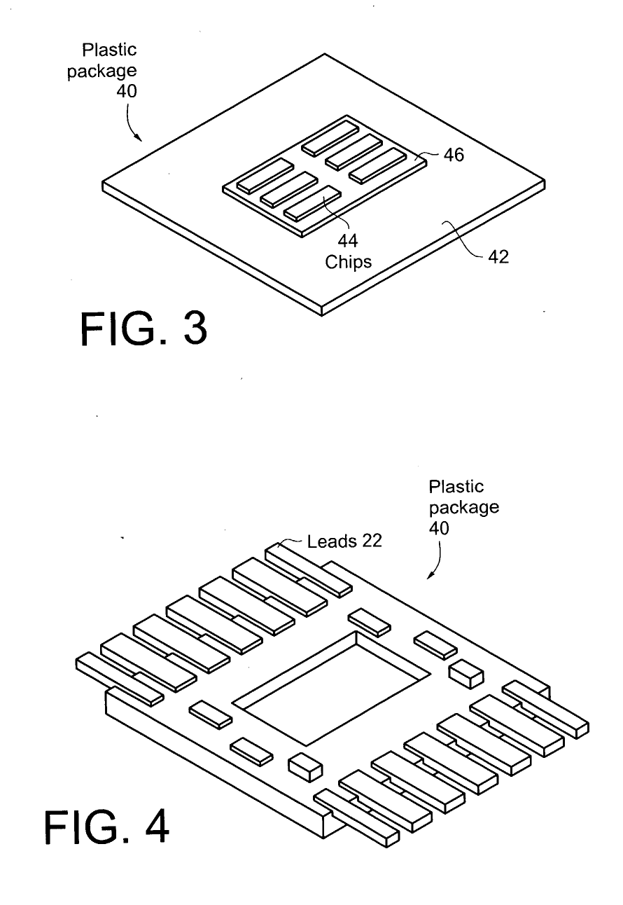

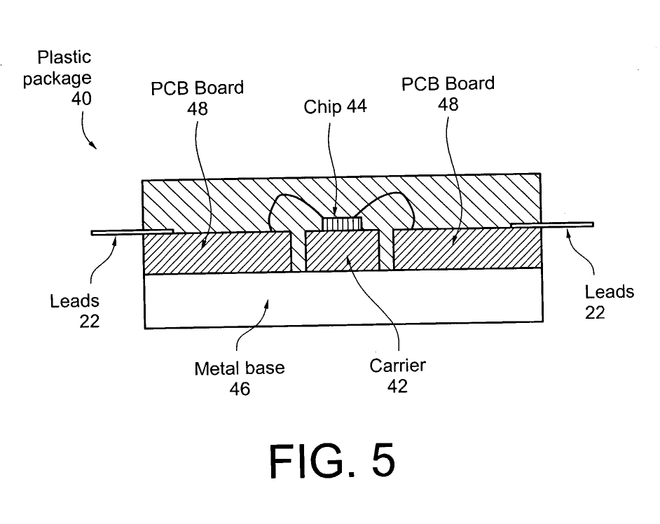

### DETAILED DESCRIPTION

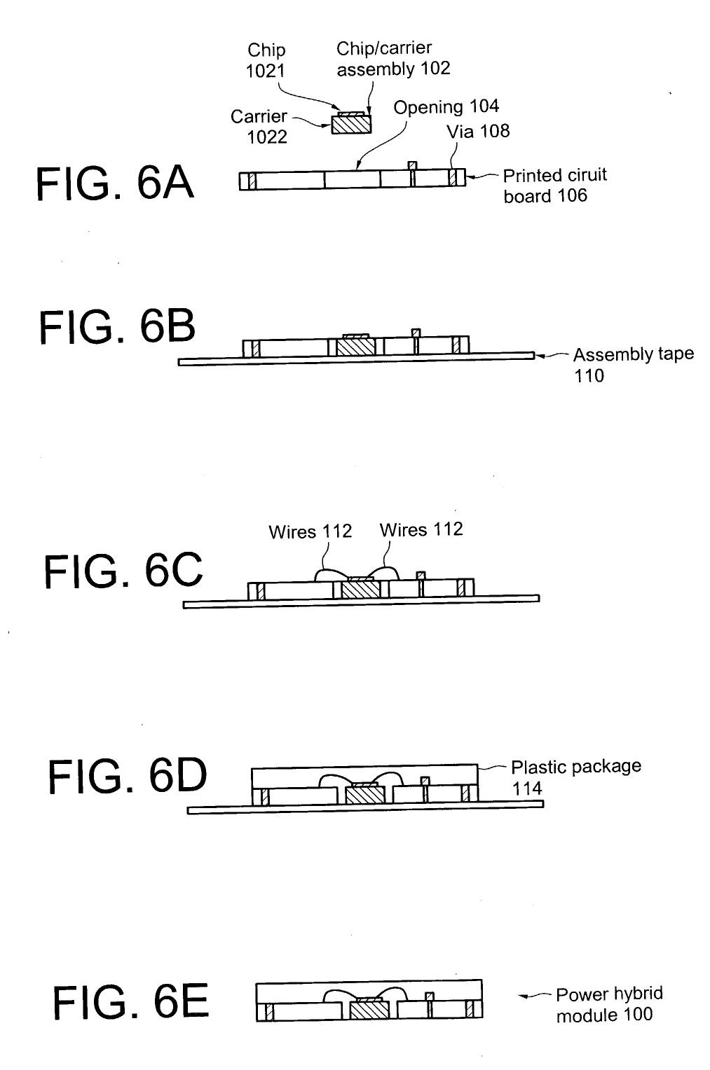

FIGS. 6A-6E illustrate an exemplary embodiment of the present invention for fabricating a power hybrid module 100. As illustrated in FIG. 6A, a chip/carrier assembly 102 is placed in an opening 104 defined in a printed circuit board 106. The chip/carrier assembly 102 includes a chip or die 1021 and a carrier 1022. The printed circuit board 106 has vias 108 through to a bottom surface of the printed circuit board 106. Thus, the printed circuit board 106 is adapted to be compatible to surface mount technology. Impedance matching circuitry 107, such as one or more SiON gold (Au) metal capacitors, may also be provided on the printed circuit board 106. Temperature control circuitry may also be provided on the printed circuit board 106.

In order to ensure that the path from the chip/carrier assembly 102 to a heat sink is acceptably short, the printed circuit board 106 and the chip/carrier assembly 102 are placed on an assembly tape 110, as illustrated in FIG. 6B. The assembly tape 110 may be resistant to high temperature, such as over 180° C. and have a thickness of 0.1 to 0.25 mm. The assembly tape may be Kapton tape. The chip/carrier assembly 102 is then wire bonded to the printed circuit board 106 with wires 112, as illustrated in FIG. 6C.

As illustrated in FIG. 6D, the chip/carrier assembly 102 is overmolded using conventional materials and conditions for overmolding, for example, a plastic package 114, onto an integrated circuit. After the plastic package 114 is in place, thereby securing the chip/carrier assembly 102 and the printed circuit board 106, the assembly tape 110 is removed thereby exposing the vias 108 and any pattern on the carrier 1022.

The plastic package 114 can be surface mounted on another board or can be placed directly on a heat sink to ensure efficient thermal conductivity of heat from the plastic package 114 to the heat sink. Surface mounting improves thermal performance and/or reduces thermal resistance of the plastic package 114. Surface mounting also may lower the junction temperature of any transistors contained in any of chips 1021, thereby improving the electrical performance (i.e. maximum power out, efficiency, reliability etc.) of the chips 1021. The plastic package 114 also contains the requisite impedance matching component/circuits, which are embedded in the printed circuit board 106 that is embedded in the plastic package 114.

The exemplary method of FIGS. 6A-6D also enables several plastic packages 114 to be produced simultaneously, similar to mass production. For example, in FIG. 6A, several chip/carrier assemblies 102 may be placed in several openings 104 defined in one or more printed circuit boards 106. In FIG. 6B, several printed circuit boards 106 and/or chip/carrier assemblies 102 may be placed on the assembly tape 110.

The chip/carrier assemblies 102 may then be wire bonded to the printed circuit boards 106 with wires 112, as illustrated in FIG. 6C. As illustrated in FIG. 6D, all the chip/carrier assemblies 102 can be overmolded. After the plastic package 114 is in place, thereby securing the chip/carrier assemblies 102 on their respective printed circuit boards 106, the assembly tape 110 is removed thereby exposing the vias 108 and any pattern on the carriers 1022. The multiple power hybrid modules can then be singulated, by cutting them into individual units.

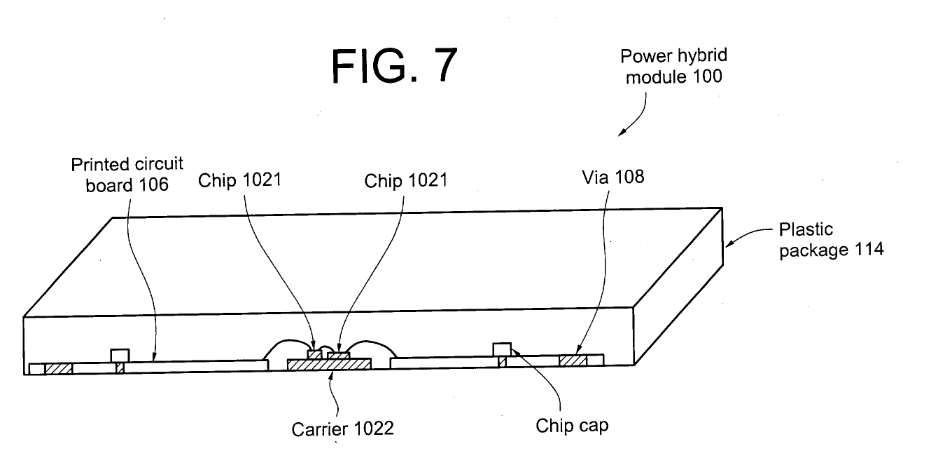

An exemplary plastic package 114 is illustrated in more detail in FIG. 7. As illustrated in FIG. 7, the chips 1021 may be a MOS cap (for example 1×5 mm), the printed circuit board 106 may be 15 mm, and the carrier 1022 may be 20 mm and made of copper (Cu). The plastic package 114 produced from the process illustrated and illustrated in FIG. 7 is a simpler, surface mount, which is capable of selective impedance matching (for example, 6Ω or 50Ω), provides improved thermal properties, namely 5 to 10 times better than conventional CuW and provides a platform for added capabilities, such as temperature and bias control, linearization, etc. The plastic package 114 illustrated in FIG. 7 is also cheaper than the conventional CuW package.

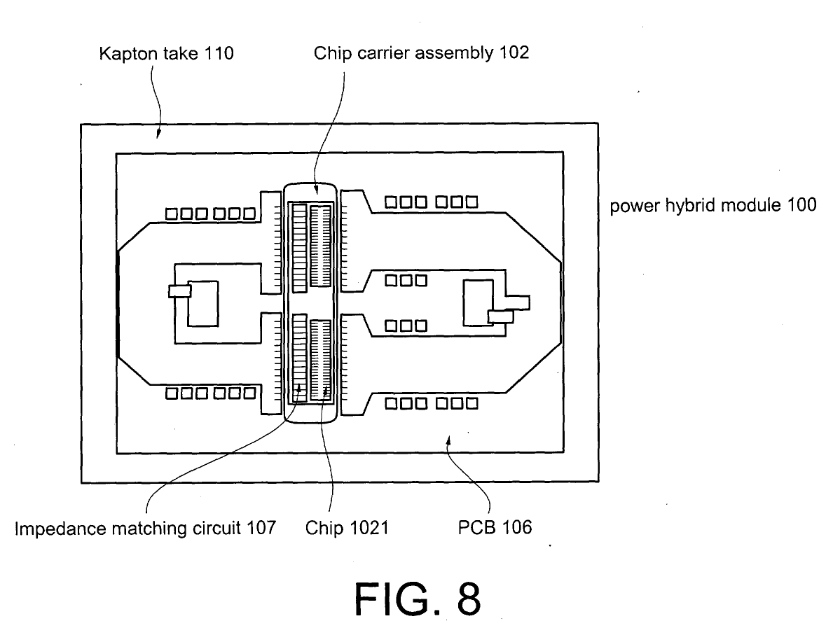

FIG. 8 is a photograph of a power hybrid module 100 in accordance with another exemplary embodiment of the present invention.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims. For example, the chip/carrier assembly 102 could be omitted and the chip 1021 (or die) could be surface mounted directly on the printed circuit board to thereby expose the backside of the chip. Additionally, the chip/carrier assembly 102 could be mounted on a pedestal instead of on a printed circuit board with vias. Other such modifications that would be obvious to one skilled in the art are also intended to be included within the scope of the following claims.

1. A process for fabricating a power hybrid module, comprising:
placing at least one carrier assembly in at least one opening in at least one printed circuit board;
mounting the at least one carrier assembly and the at least one printed circuit board on assembly tape;
electrically connecting one of the at least one carrier assemblies and one of the at least one printed circuit boards;
overmolding the at least one carrier assembly and the at least one printed circuit board; and
removing the assembly tape to produce a surface mount power hybrid module.

2. The process of claim 1, wherein several carrier assemblies are placed in several openings in several printed circuit boards, said process further comprising:
singulating the several carrier assemblies.

3. The process of claim 1, further comprising:
mounting impedance matching circuitry on the at least one printed circuit board.

4. The process of claim 1, wherein the at least one carrier assembly includes at least one die and at least one carrier.

5. The process of claim 1, wherein the assembly tape is Kapton tape.

6. The process of claim 1, wherein the overmolding is performed with plastic.

7. A power hybrid module, comprising:
at least one printed circuit board with at least one opening therein;
at least one carrier assembly, positioned in the at least one opening such that said at least one carrier assembly may be surface mounted and electrically connected to said at least one printed circuit board; and
an overmold over said at least one printed circuit board and said at least one carrier assembly.

8. The power hybrid module of claim 7, said at least one carrier assembly including at least one die and at least one carrier.

9. The power hybrid module of claim 7, wherein the overmold is made of plastic.

10. The power hybrid module of claim 7, further comprising impedance matching circuitry.

11. The power hybrid module of claim 7, said at least one printed circuit board including at last one via.

12. A process for fabricating a power hybrid module, comprising:
placing at least one die in at least one opening in at least one printed circuit board;
mounting the at least one die and the at least one printed circuit board on assembly tape;
electrically connecting one of the at least one dies and one of the at least one printed circuit boards;
overmolding the at least one die and the at least one printed circuit board; and
removing the assembly tape to produce a surface mount power hybrid module.

13. The process of claim 12, wherein several dies are placed in several openings in several printed circuit boards, said process further comprising:
singulating the several dies.

14. The process of claim 12, further comprising:
mounting impedance matching circuitry on the at least one printed circuit board.

15. The process of claim 12, wherein the assembly tape is Kapton tape.

16. The process of claim 12, wherein the overmolding is performed with plastic.

17. A power hybrid module, comprising:
at least one printed circuit board with at least one opening therein;
at least one die, positioned in the at least one opening such that said at least one die may be surface mounted and electrically connected to said at least one printed circuit board; and
an overmold over said at least one printed circuit board and said at least one die.

18. The power hybrid module of claim 17, wherein the overmold is made of plastic.

19. The power hybrid module of claim 17, further comprising impedance matching circuitry.

20. The power hybrid module of claim 7, said at least one printed circuit board including at last one via.
